(19) United States
(12) Patent Application Publication
(10) Pub. No.: US 2026/0279747 A1
(43) Pub. Date: Sep. 17, 2026

(54) PLASMA MEASUREMENT METHOD AND PLASMA MEASUREMENT SYSTEM

(71) Applicant: Tokyo Electron Limited, Tokyo (JP)

(72) Inventor: Eiki KAMATA, Nirasaki City (JP)

(21) Appl. No.: 19/529,549

(22) Filed: Feb. 4, 2026

(30) Foreign Application Priority Data
Feb. 10, 2025 (JP) 2025-020272

(51) Int. Cl. H01J 37/32

(52) U.S. Cl. CPC H01J 37/32954; H01J 37/32862; H01J 37/32926; H01J 37/32972; H01J 37/3299; H01J 37/32201; H01J 2237/24514; H01J 2237/24585; H01J 2237/332

(57) ABSTRACT

There is provided a plasma measurement method of measuring a state of plasma using a plasma measurement system. The plasma measurement system includes a probe device provided in a plasma processing apparatus and a measurement circuit including a signal generator configured to output an alternating-current voltage. The plasma measurement method includes acquiring, by the measurement circuit via the probe device, data including at least fundamental harmonic data and second harmonic data during plasma processing of a prescribed unit, and deriving a plasma state parameter and a parameter of the measurement circuit based on the acquired data.

### CROSS-REFERENCE TO RELATED APPLICATION

This application is based upon and claims the benefit of priority from Japanese Patent Application No. 2025-020272, filed on Feb. 10, 2025, the entire contents of which are incorporated herein by reference.

### TECHNICAL FIELD

The present disclosure relates to a plasma measurement method and a plasma measurement system.

### BACKGROUND

Patent Document 1 discloses a plasma probe device including an antenna part installed in an opening formed in a wall of a processing container or in a stage via a sealing member that seals between a vacuum space and an atmospheric space, an electrode connected to the antenna part, and a dielectric support formed of a dielectric to support the antenna part from a periphery of the antenna part. Surfaces of the antenna part and the wall or the stage which face each other are separated by a predetermined width, and a surface of the antenna part exposed from the opening is depressed compared to a surface on the side of a plasma generation space in the wall or the stage in which the opening is formed.

### PRIOR ART DOCUMENTS

### Patent Documents

Patent Document 1: Japanese Laid-Open Patent Publication No. 2019-046787

### SUMMARY

According to one embodiment of the present disclosure, there is provided a plasma measurement method of measuring a state of plasma using a plasma measurement system. The plasma measurement system includes: a probe device provided in a plasma processing apparatus; and a measurement circuit including a signal generator configured to output an alternating-current voltage. The plasma measurement method includes: acquiring, by the measurement circuit via the probe device, data including at least fundamental harmonic data and second harmonic data during plasma processing of a prescribed unit; and deriving a plasma state parameter and a parameter of the measurement circuit based on the acquired data.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view illustrating an example of a plasma processing apparatus according to one embodiment.

FIG. 2 is a diagram illustrating an example of a cross section taken along line A-A of FIG. 1.

FIG. 3 is a diagram illustrating exemplary functional configurations of a measurement system and a control device according to one embodiment.

FIG. 4 is a flowchart illustrating an example of a control method of the plasma processing apparatus.

FIGS. 5A and 5B are an example of a circuit model of the measurement system.

FIG. 6 is a graph illustrating an example of results of estimated plasma electron temperature.

FIG. 7 is a graph illustrating an example of results of estimated plasma electron density.

FIG. 8 is a graph illustrating an example of detected amplitudes of a real part and an imaginary part of a fundamental current harmonic.

FIG. 9 is a graph illustrating an example of detected amplitudes of a real part and an imaginary part of a second current harmonic.

FIG. 10 is a graph illustrating an example of extracted amplitudes of the real part and the imaginary part of the fundamental current harmonic.

FIG. 11 is a graph illustrating an example of extracted amplitudes of the real part and the imaginary part of the second current harmonic.

FIG. 12 is a graph illustrating an example of further extracted amplitudes of the real part and the imaginary part of the fundamental current harmonic.

FIG. 13 is a graph illustrating an example of further extracted amplitudes of the real part and the imaginary part of the second current harmonic.

FIG. 14 is a graph illustrating an example of fitted amplitudes of the real part and the imaginary part of the fundamental current harmonic.

FIG. 15 is a graph illustrating an example of fitted amplitudes of the real part and the imaginary part of the second current harmonic.

### DETAILED DESCRIPTION

Hereinafter, embodiments for carrying out the present disclosure will be described with reference to the drawings. In each drawing, the same reference numerals may be given to the same components, and redundant descriptions thereof may be omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Plasma Processing Apparatus

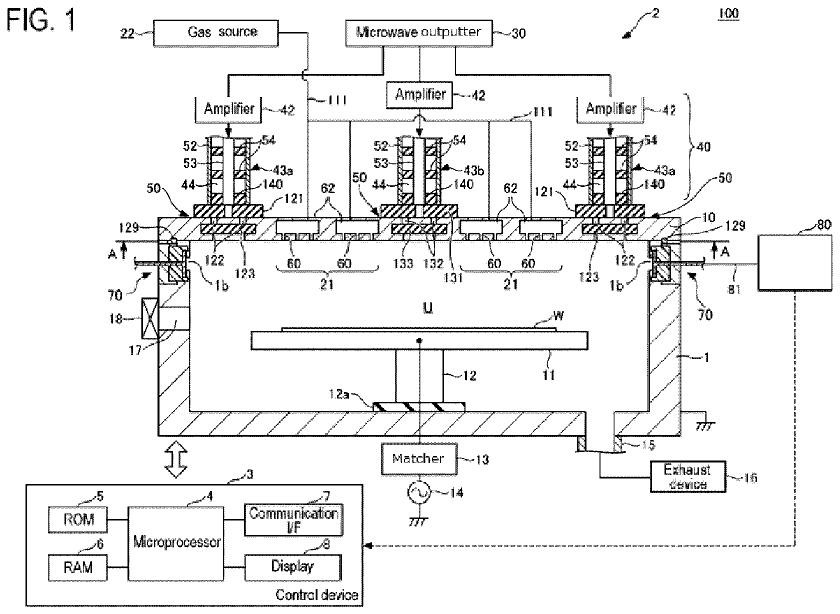

FIG. 1 illustrates an example of a cross-sectional view of a plasma processing apparatus 100 according to one embodiment of the present disclosure. The plasma processing apparatus 100 includes a processing container 1 that accommodates a substrate W, which is, for example, a semiconductor wafer. The plasma processing apparatus 100 is an example of a plasma processing apparatus that performs plasma processing on the substrate W using a surface wave plasma, which is formed on a lower surface of a ceiling wall 10 of the processing container 1 by microwaves. Film formation processing, etching processing, or ashing processing using plasma is exemplified as the plasma processing.

The plasma processing apparatus 100 includes the processing container 1, a microwave plasma source 2, and a control device 3. The processing container 1 is a substantially airtight cylindrical container made of a metallic material such as aluminum or stainless steel and is grounded.

The processing container 1 includes the ceiling wall 10, and has an interior defined as a space (plasma generation space U) in which the plasma processing is performed on the substrate W. The ceiling wall 10 is a disk-shaped lid that blocks an opening of an upper portion of the processing container 1. A support ring 129 is provided at a contact surface between the processing container 1 and the ceiling wall 10, thereby airtightly sealing the interior of the processing container 1. The ceiling wall 10 is made of a metallic material such as aluminum or stainless steel.

The microwave plasma source 2 includes a microwave outputter 30, a microwave transmitter 40, and a microwave radiation mechanism 50. The microwave outputter 30 outputs microwaves to be distributed into a plurality of paths. The microwaves are introduced into the interior of the processing container 1 via the microwave transmitter 40 and the microwave radiation mechanism 50. A gas supplied into the processing container 1 is excited by an electric field of the introduced microwaves, thereby forming a surface wave plasma.

A stage 11 on which the substrate W is placed is provided in the interior of the processing container 1. The stage 11 is supported by a cylindrical support member 12 provided upright on the center of the bottom of the processing container 1 via an insulating member 12a. Examples of materials constituting the stage 11 and the support member 12 include a metal such as aluminum whose surface is alumite-treated (anodized), and an insulating member (such as ceramics) having an electrode for radio frequency in an interior thereof. The stage 11 may further be provided with an electrostatic chuck for electrostatically attracting the substrate W, a temperature control mechanism, a gas flow path through which a heat-transfer gas is supplied to a rear surface of the substrate W, and the like.

A radio-frequency bias power supply 14 is connected to the stage 11 via a matcher 13. By supplying radio-frequency power from the radio-frequency bias power supply 14 to the stage 11, ions in the plasma are drawn toward the substrate W. Further, the radio-frequency bias power supply 14 may be omitted according to characteristics of the plasma processing.

An exhaust pipe 15 is connected to the bottom of the processing container 1. An exhaust device 16 including a vacuum pump is connected to the exhaust pipe 15. When the exhaust device 16 is operated, the interior of the processing container 1 is exhausted. This rapidly depressurizes the interior of the processing container 1 to a predetermined degree of vacuum. A loading/unloading port 17 through which the substrate W is loaded and unloaded, and a gate valve 18 for opening or closing the loading/unloading port 17 are provided in a sidewall of the processing container 1.

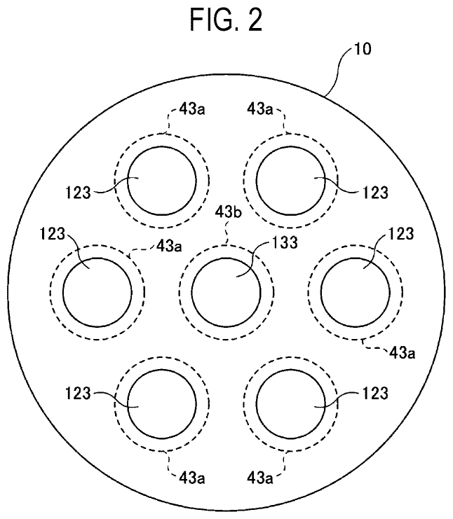

The microwave transmitter 40 transmits the microwaves output from the microwave outputter 30. FIG. 2 illustrates a cross section taken along line A-A of FIG. 1, and illustrates an example of a lower surface of a ceiling wall of the plasma processing apparatus 100. Referring to FIG. 2, a central microwave introducer 43b in the microwave transmitter 40 is located at the center of the ceiling wall 10, and six circumferential microwave introducers 43a are located circumferentially at equal intervals at a periphery of the ceiling wall 10. The central microwave introducer 43b and the six circumferential microwave introducers 43a have a function of introducing the microwaves output from amplifiers 42 illustrated in FIG. 1, which are provided to correspond to respective introducers, into the microwave radiation mechanism 50, and a function of performing an impedance matching. Hereinafter, the six circumferential microwave introducers 43a and the central microwave introducer 43b are collectively referred to as a microwave introducer 43.

As illustrated in FIGS. 1 and 2, six outer-peripheral dielectric windows 123 are arranged inside the ceiling wall 10 below the six circumferential microwave introducers 43a. Further, one central dielectric window 133 is arranged inside the ceiling wall 10 below the central microwave introducer 43b. In addition, the number of circumferential microwave introducers 43a and the number of dielectric windows 123 are not limited to six, and may be two or more. Preferably, the number of circumferential microwave introducers 43a may be three or more, for example, three to six.

The microwave radiation mechanism 50 illustrated in FIG. 1 includes slow-wave plates 121 and 131, slots 122 and 132, and the dielectric windows 123 and 133. The slow-wave plates 121 and 131 are formed of disk-shaped dielectrics that transmit microwaves therethrough, and are disposed on an upper surface of the ceiling wall 10. The slow-wave plates 121 and 131 are formed of, for example, ceramics such as quartz and alumina (Al₂O₃), fluorine-based resins such as polytetrafluoroethylene, or polyimide-based resins, which have a relative dielectric constant higher than a vacuum. Thus, the slow-wave plates 121 and 131 function to make the wavelength of the microwaves transmitted through the slow-wave plates 121 and 131 shorter than that of the microwaves propagating in the vacuum, thereby downsizing an antenna including the slots 122 and 132.

Below the slow-wave plates 121 and 131, the dielectric windows 123 and 133 are brought into contact with an inner surface around an opening of the ceiling wall 10 via the slots 122 and 132 formed in the ceiling wall 10. The dielectric windows 123 and 133 are formed of, for example, ceramics such as quartz and alumina (Al₂O₃), fluorine-based resins such as polytetrafluoroethylene, or polyimide-based resins. The dielectric windows 123 and 133 are provided at positions depressed from a ceiling surface by a thickness of the opening formed in the ceiling wall 10, and supply the microwaves to the plasma generation space U.

Each of the circumferential microwave introducers 43a and the central microwave introducer 43b is arranged coaxially with a cylindrical outer conductor 52 and a rod-shaped inner conductor 53 provided at the center of the outer conductor 52. Microwave power is supplied between the outer conductor 52 and the inner conductor 53 so that a microwave transmission path 44 through which the microwaves propagate toward the microwave radiation mechanism 50 is formed.

Each of the circumferential microwave introducers 43a and the central microwave introducer 43b is provided with a slag 54 and an impedance adjustment member 140 located at a tip portion of the slag 54. By moving the slag 54, an impedance of a load (plasma) in the interior of the processing container 1 may be matched with a characteristic impedance of a microwave power supply in the microwave outputter 30. The impedance adjustment member 140 is formed of a dielectric and is configured to adjust the impedance of the microwave transmission path 44 by the relative dielectric constant thereof.

A gas introducer 21 having a shower structure is provided in the ceiling wall 10. A gas supplied from a gas source 22 passes through a gas supply pipe 111 and is supplied in the form of a shower from a gas diffusion chamber 62 into the processing container 1 via the gas introducer 21. The gas introducer 21 is an example of a gas shower head that supplies a gas from a plurality of gas supply holes 60 formed in the ceiling wall 10. Examples of the gas may include a plasma generation gas such as an Ar gas, a gas to be decomposed with high energy such as an O₂ gas and N₂ gas, and a processing gas such as a silane gas.

Individual constituent elements of the plasma processing apparatus 100 are controlled by the control device 3. The control device 3 includes a microprocessor 4, a read only memory (ROM) 5, and a random access memory (RAM) 6. The ROM 5 and the RAM 6 store process sequences and process recipes, which are control parameters, of the plasma processing apparatus 100. The microprocessor 4 controls the individual constituent elements of the plasma processing apparatus 100 based on the process sequences and the process recipes. Further, the control device 3 includes a communication interface (I/F) 7 and is capable of communicating with other devices. Further, the control device 3 includes a display 8, and is capable of displaying results available when performing a predetermined control according to the process sequences and the process recipes.

When performing the plasma processing in the plasma processing apparatus 100 configured as above, first, the substrate W is loaded into the processing container 1 via the loading/unloading port 17 from the opened gate valve 18 in a state of being held by a transfer arm (not illustrated). Once the substrate W has been transferred above the stage 11, the substrate is delivered from the transfer arm to pusher pins, and is placed on the stage 11 by lowering the pusher pins. The gate valve 18 is closed after loading the substrate W. An internal pressure of the processing container 1 is maintained at a predetermined degree of vacuum by the exhaust device 16. The processing gas is introduced into the processing container 1 from the gas introducer 21 in the form of a shower. The microwaves radiated from the microwave radiation mechanism 50 propagate in the vicinity of the inner surface, that is, a lower surface of the ceiling wall 10 via the microwave introducers 43. The gas is excited by the electric field of the surface wave microwaves, and the substrate W is subjected to the plasma processing using surface wave plasma generated in the plasma generation space U below the ceiling wall 10 of the processing container 1.

### Probe Device

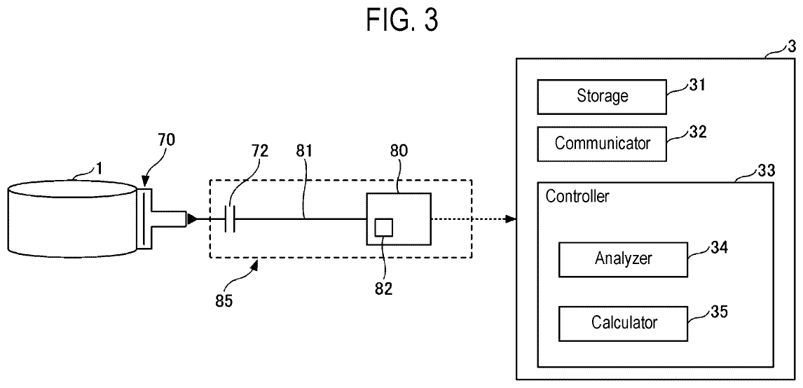

A probe device 70 will be described below with reference to FIGS. 1 and 3. FIG. 3 is a diagram illustrating exemplary functional configurations of a measurement system and a control device according to one embodiment. As illustrated in FIG. 1, one or more openings 1b are formed circumferentially in the sidewall of the processing container 1, and one or more probe devices 70 are attached to the one or more openings 1b via sealing members (not illustrated) that seal between a vacuum space and an atmospheric space.

A gap having a predetermined width is formed between a tip surface of each probe device 70 and the inner surface around the opening 1b formed in the sidewall of the processing container 1. The gap is designed to be a space that is wide enough so that the probe device 70 is not galvanically connected to the sidewall of the processing container 1 but is narrow enough so that plasma or gas does not enter. In this case, the probe device 70 may be attached to an opening formed in the stage 11 via a sealing member.

As illustrated in FIG. 3, the measurement system for measuring a state of the plasma is constituted with the probe device 70 and a measurement circuit 85. The measurement circuit 85 includes a monitor device 80, a blocking capacitor 72, and a coaxial cable 81. The monitor device 80 is communicably connected to the control device 3.

The probe device 70 is connected to the monitor device 80 via the coaxial cable 81 outside the plasma processing apparatus 100. The monitor device 80 includes a signal generator 82. The signal generator 82 outputs an AC voltage signal with a predetermined frequency to the coaxial cable 81. The AC voltage signal is transmitted to the coaxial cable 81, and an AC voltage is applied to the probe device 70. The blocking capacitor 72 is connected to the coaxial cable 81, transmits the AC voltage signal to the probe device 70, and blocks a DC voltage signal. Thus, the monitor device 80 receives only the AC voltage signal from the side of the plasma.

The probe device 70 senses the plasma generated in the plasma generation space U. The probe device 70 detects a current signal that has flowed toward the plasma with respect to the signal transmitted to the side of the plasma, and transmits the same to the monitor device 80. The current signal that has flowed toward the plasma is transmitted from the monitor device 80 to the control device 3, and is received by a communicator 32 of the control device 3. A current value of the received signal is stored in a storage 31. An analyzer 34 of a controller 33 analyzes the current value of the received signal using Fast Fourier Transform (FET). A calculator 35 of the controller 33 calculates a plasma electron temperature Tₑ and a plasma electron density nₑ based on the analyzed result. Thus, the state of the plasma may be accurately estimated. As described above, the plasma measurement system for measuring the state of the plasma includes the probe device 70, the measurement circuit 85, and the control device 3 (the controller 33).

In addition, the storage 31 is implemented by the RAM 6 illustrated in FIG. 1. The communicator 32 is implemented by the communication interface 7. The analyzer 34 and the calculator 35 of the controller 33 are implemented by the microprocessor 4.

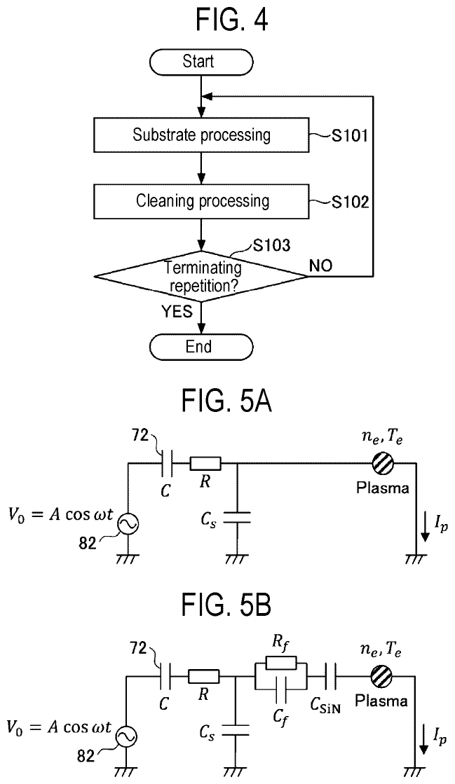

FIG. 4 is a flowchart illustrating an example of a method of controlling the plasma processing apparatus 100.

In Step S101, substrate processing is performed. Here, the control device 3 controls the gas source 22 to supply the processing gas (for example, a film formation gas or etching gas) into the plasma generation space U via the gas supply holes 60, and controls the microwave outputter 30 and the radio-frequency bias power supply 14 to generate the plasma of the processing gas in the plasma generation space U, thus performing desired processing (for example, film formation processing or etching processing) on the substrate W. At this time, the probe device 70 receives the AC voltage from the signal generator 82 and senses the plasma generated in the plasma generation space U. Then, the controller 33 calculates the plasma electron temperature Tₑ and the plasma electron density nₑ to estimate the state of the plasma.

Here, in a case in which the substrate processing is processing for forming an insulating film on the substrate W, an insulator (for example, SiN, SiO₂, or the like) is deposited on a surface of the probe device 70 exposed to the plasma generation space U (such as the tip surface of the probe device 70) to form an insulating film. In addition, the substrate processing is not limited to the processing for forming the insulating film, and may also be processing (for example, etching processing) in which an insulator is formed as a reaction by-product and the reaction by-product (insulator) is deposited on the surface of the probe device 70 exposed to the plasma generation space U to form an insulating film.

In Step S101, the substrate processing is repeated until a cleaning start condition such as a predetermined number of processed substrates or a processing time is satisfied. When the predetermined cleaning start condition is satisfied, the processing of the control device 3 proceeds to Step S102.

In Step S102, cleaning processing such as dry cleaning processing (cleaning processing using a cleaning gas without exposing the processing container to the atmosphere) is performed. In this case, the control device 3 controls the gas source 22 to supply a cleaning gas containing fluorine (F) (for example, NF₃) into the plasma generation space U via the gas supply holes 60, and controls the microwave outputter 30 and/or the radio-frequency bias power supply 14 to generate a plasma of the cleaning gas in the plasma generation space U, and remove the insulating film deposited in the interior of the processing container 1. Further, the insulating film deposited on the surface of the probe device 70 exposed to the plasma generation space U is also removed.

In this case, in the cleaning processing, a fluoride having conductivity adheres to and is deposited on the surface of the probe device 70 exposed to the plasma generation space U to form a conductive film. The fluoride having conductivity is, for example, a metal fluoride (for example, AlF) containing a metal (for example, Al) derived from the inner wall of the processing container 1 or the dielectric windows 123 and 133 formed of alumina (Al₂O₃) and fluorine (F) derived from the cleaning gas. The deposited metal fluoride has lattice defects, and thus has conductivity.

In Step S103, it is determined whether or not the repetition of the substrate processing is terminated. When it is determined that the repetition is not terminated (NOT in S103), the processing of the control device 3 returns to Step S101 to repeat the substrate processing and the cleaning processing. When it is determined that the repetition is terminated (YES in S103), the processing of the control device 3 is terminated. Further, cleaning processing such as wet cleaning (cleaning processing in which the processing container is exposed to the atmosphere) is performed.

### Circuit Model

FIGS. 5A and 5B are examples of a circuit model of the measurement system. FIG. 5A is an example of a circuit model of the probe device 70. FIG. 5B illustrates an example of a circuit model in a case where an insulating film and a conductive film are formed on the surface of the probe device 70 exposed to the plasma generation space U.

As illustrated in FIG. 5A, the circuit model includes the signal generator 82 and a plasma, which serves as a load, arranged in series, and a current Iₚ flows from the signal generator 82 to the plasma. Further, the circuit model includes a capacitance C of the blocking capacitor 72 arranged in series with the signal generator 82. Further, the circuit model includes a resistor R arranged in series with the signal generator 82. In addition, the resistor R is used to measure the current Iₚ flowing into the plasma, and a resistance value thereof is known and is assumed to be sufficiently small compared to the resistance value of the plasma. The current Iₚ flowing into the plasma is measured by measuring a voltage across the resistor R. Further, the circuit model includes a parasitic capacitance Cₛ in parallel with the signal generator 82.

The controller 33 estimates the state of the plasma (the plasma electron temperature Tₑ and the plasma electron density nₑ) based on the current Iₚ detected by the resistor R and the circuit model.

Further, when forming the insulating film on the substrate W during the substrate processing (S101), the insulating film is also deposited on the surface of the probe device 70. In addition, the insulating film deposited on the surface of the probe device 70 is removed by the dry cleaning processing (S102).

As illustrated in FIG. 5B, in the state in which the insulating film is formed on the surface of the probe device 70, the insulating film exhibits a capacitive component C_{SiN}. The capacitive component C_{SiN} is arranged in series with the capacitance C of the blocking capacitor 72. In this case, by regarding the plasma as a pure resistance with a phase difference of 0° and the insulating film as having the capacitive component C_{SiN} with a phase difference of 90°, the thickness of the insulating film (the capacitive component C_{SiN}) and the state of the plasma (the plasma electron temperature Tₑ and the plasma electron density nₑ) may be estimated separately.

Further, by the dry cleaning processing (S102), a conductive film (for example, a conductive metal fluoride film) is deposited on the surface of the probe device 70. In addition, the conductive film deposited on the surface of the probe device 70 is removed by the wet cleaning processing.

As illustrated in FIG. 5B, in a state in which the conductive film is formed on the surface of the probe device 70, the conductive film exhibits a resistive component R_{f} and a capacitive component C_{f}.

In addition, when the resistive component R_{f} is close to 0Ω (that is, regarded as a conductor), the presence of the capacitive component C_{f} may be ignored and the conductive film may be treated as a conducting wire, and the state of the plasma may be estimated by the same calculation as in FIG. 5A, assuming that the capacitive component C_{SiN} is in series with the capacitance C of the blocking capacitor 72. Further, when the resistive component R_{f} is close to ∞Ω, the presence of the resistive component R_{f} may be ignored and only the capacitive component C_{f} needs to be considered, and the state of the plasma may be estimated by the same calculation as in FIG. 5A, assuming that the capacitive component C_{SiN} and the capacitive component C_{f} are arranged in series with the capacitance C of the blocking capacitor 72.

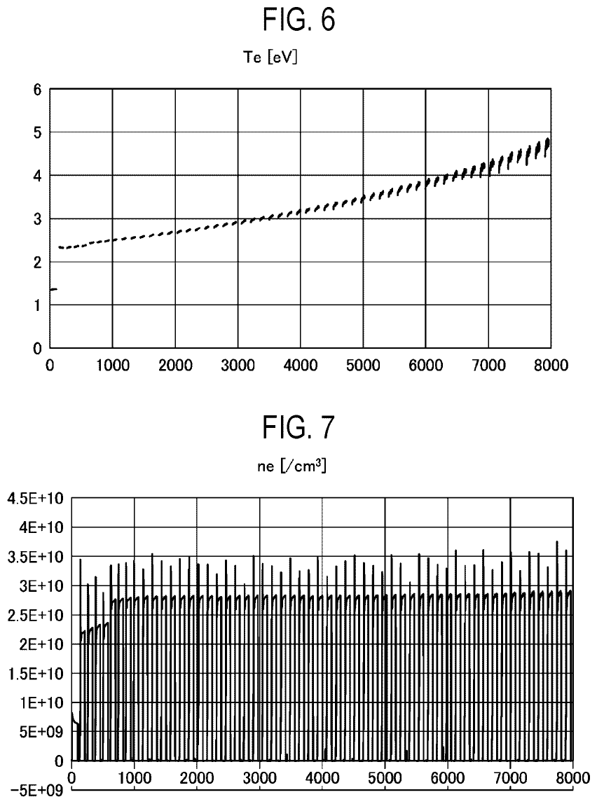

On the other hand, in a state in which the conductive film is formed, when the conductive film has finite conductivity (in other words, when the resistive component R_{f} has a value not so small as to be regarded as 0Ω and not so large as to be regarded as ∞Ω, but instead falls within an intermediate range between these values), the calculation used in FIG. 5A may not properly estimate the plasma electron temperature Tₑ. That is, when the conductive film has a finite resistance component R_{f}, the resistive component R_{f} may be added to the resistive component of the plasma. As a result, it is impossible to determine whether a change in current when measuring the plasma is caused by the plasma itself or by the fluoride film. Therefore, as illustrated in FIG. 6 described later, the estimated plasma electron temperature Tₑ may deviate from a true value thereof as the conductive film accumulates over time, which may result in a degradation in estimation accuracy. In particular, when the conductive film is AlF, the impedance of the resistive component R_{f} and the impedance of the capacitive component C_{f} are approximately the same, which increases an estimation.

### Method of Measuring State of Plasma

The probe device 70 detects a current value (current Iₚ). The analyzer 34 analyzes the current value detected by the probe device 70 using Fast Fourier Transform (FFT). Thus, the current value is decomposed into frequency components such as a fundamental harmonic component (1ω component) and a second harmonic component (2ω component). Specifically, the analyzer 34 detects “the amplitude of the fundamental current harmonic,” “the phase of the fundamental current harmonic,” “the amplitude of the second current harmonic,” and “the phase of the second current harmonic.”

The calculator 35 obtains the resistive component R_{f} of the conductive film, the capacitive component C_{f} of the conductive film, the plasma electron temperature Tₑ, and the plasma electron density nₑ based on four independent parameters detected by the analyzer 34 (the amplitude of the fundamental current harmonic, the phase of the fundamental current harmonic, the amplitude of the second current harmonic, and the phase of the second current harmonic). In other words, the calculator 35 determines the state of the conductive film (the resistive component R_{f} and the capacitive component C_{f}) and the state of the plasma (the plasma electron temperature Tₑ and the plasma electron density nₑ) based on the four independent parameters detected by the analyzer 34 (the amplitude of the fundamental current harmonic, the phase of the fundamental current harmonic, the amplitude of the second current harmonic, and the phase of the second current harmonic).

In addition, an amplitude of a real part of the fundamental current harmonic and an amplitude of an imaginary part of the fundamental current harmonic may be obtained from the amplitude of the fundamental current harmonic and the phase of the fundamental current harmonic. Further, an amplitude of a real part of the second current harmonic and an amplitude of an imaginary part of the second current harmonic may be obtained from the amplitude of the second current harmonic and the phase of the second current harmonic.

Therefore, the calculator 35 obtains the resistive component R_{f} of the conductive film, the capacitive component C_{f} of the conductive film, the plasma electron temperature Tₑ, and the plasma electron density nₑ based on the four independent parameters detected by the analyzer 34 (the amplitude of the real part of the fundamental current harmonic, the amplitude of the imaginary part of the fundamental current harmonic, the amplitude of the real part of the second current harmonic, and the amplitude of the imaginary part of the second current harmonic). In other words, the calculator 35 determines the state of the conductive film (the resistive component R_{f} and the capacitive component C_{f}) and the state of the plasma (the plasma electron temperature Tₑ and the plasma electron density nₑ) based on the four independent parameters detected by the analyzer 34 (the amplitude of the real part of the fundamental current harmonic, the amplitude of the imaginary part of the fundamental current harmonic, the amplitude of the real part of the second current harmonic, and the amplitude of the imaginary part of the second current harmonic).

FIG. 6 is a graph illustrating an example of results of the estimated plasma electron temperature Tₑ. In FIG. 6, the horizontal axis represents the number of processed substrates W, and the vertical axis represents the estimated plasma electron temperature Tₑ. FIG. 7 is a graph illustrating an example of results of the estimated plasma electron density nₑ. In FIG. 7, the horizontal axis represents the number of processed substrates W, and the vertical axis represents the measured plasma electron density nₑ.

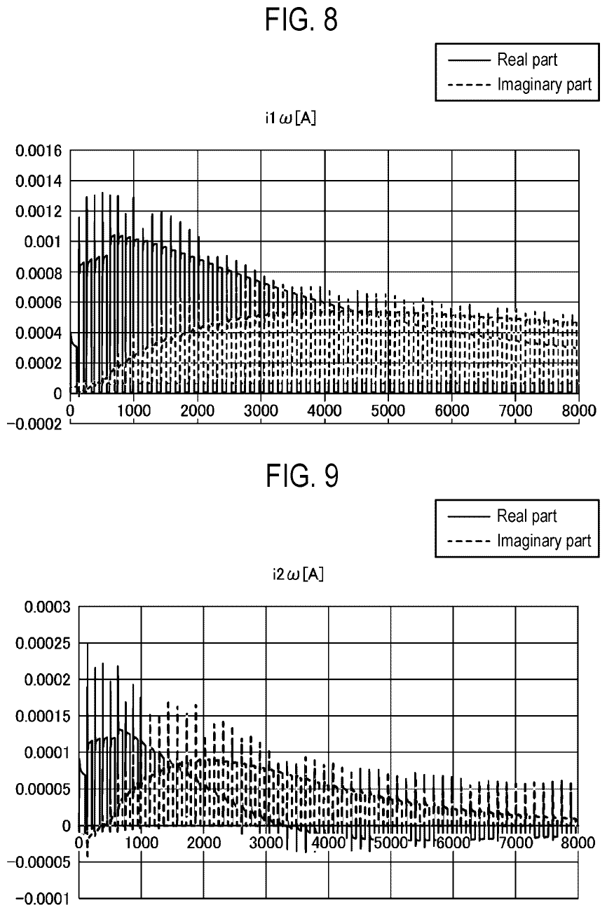

The analyzer 34 performs the FFT analysis based on the current value detected by the probe device 70, and calculates the amplitude of the real part of the fundamental current harmonic (i1ω), the amplitude of the imaginary part of the fundamental current harmonic (i1ω), the amplitude of the real part of the second current harmonic (i2ω), and the amplitude of the imaginary part of the second current harmonic (i2ω). Examples of results thus obtained are illustrated in FIGS. 8 and 9.

FIG. 8 is a graph illustrating an example of the detected amplitudes of the real part and the imaginary part of the fundamental current harmonic. In FIG. 8, the horizontal axis represents the number of processed substrates W. The vertical axis represents the amplitude of the real part of the fundamental current harmonic by a solid line, and the amplitude of the imaginary part of the fundamental current harmonic by a dashed line. FIG. 9 is a graph illustrating an example of the detected amplitudes of the real part and the imaginary part of the second current harmonic. In FIG. 9, the horizontal axis represents the number of processed substrates W. The vertical axis represents the amplitude of the real part of the second current harmonic by a solid line, and the amplitude of the imaginary part of the second current harmonic by a dashed line.

The calculator 35 determines the state of the plasma (the plasma electron temperature Tₑ illustrated in FIG. 6 and the plasma electron density nₑ illustrated in FIG. 7) based on the four independent parameters detected by the analyzer 34 (the amplitude of the real part of the fundamental current harmonic, the amplitude of the imaginary part of the fundamental current harmonic, the amplitude of the real part of the second current harmonic, and the amplitude of the imaginary part of the second current harmonic). In addition, the plasma electron temperature Tₑ and the plasma electron density nₑ illustrated in FIGS. 6 and 7 are values estimated based on the circuit model illustrated in FIG. 5A. That is, the state of the plasma (the plasma electron temperature Tₑ and the plasma electron density nₑ) is determined without considering the influence of the insulating film and the conductive film.

Here, as the processing by the plasma processing apparatus 100, the dry cleaning processing (S102) is performed after every substrate processing (S101) of 50 substrates W per lot. In addition, in FIG. 6, a plurality of points are arranged side by side, but each individual point corresponds to a timing when the substrate processing (S101) of 50 substrates per lot is performed, and each interval between the points corresponds to a timing when the dry cleaning processing (S102) is performed.

During the substrate processing of one lot, a film thickness of the insulating film deposited on the surface of the probe device 70 increases each time the number of processed substrates W increases. In other words, the capacitive component C_{SiN} changes. Thus, as illustrated in FIG. 6, during the substrate processing of one lot, the estimated plasma electron temperature Tₑ slightly increases each time the number of processed substrates W increases.

Then, by performing the dry cleaning processing (S102) after terminating the substrate processing of one lot, the insulating film deposited on the surface of the probe device 70 is removed. Thus, as illustrated in FIG. 6, the plasma electron temperature Tₑ in the last round of substrate processing on a current lot is larger than the plasma electron temperature Tₑ in a first round of substrate processing on a subsequent lot.

Further, the film thickness of the conductive film deposited on the surface of the probe device 70 increases each time the dry cleaning processing (S102) is performed. In other words, the resistive component R_{f} and the capacitive component C_{f} change. Thus, as illustrated in FIG. 6, the estimated plasma electron temperature Tₑ tends to increase overall.

As described above, there is a concern that the estimated plasma electron temperature Tₑ may change as illustrated in FIG. 6 due to the influence of the insulating film and the conductive film deposited on the surface of the probe device 70. That is, it becomes difficult to distinguish whether a change in the estimated plasma electron temperature Tₑ is based on a change in the deposited film (the insulating film or the conductive film) or based on a change in the state of the plasma. Therefore, the estimation accuracy of the plasma electron temperature Tₑ and the plasma electron density nₑ may decrease.

Next, a method of estimating the state of the plasma (the plasma electron temperature Tₑ and the plasma electron density nₑ) and the state of the film, taking into account the influence of the insulating film and the conductive film, will be described.

First, the controller 33 implements an operation of acquiring data during plasma processing of a prescribed unit using the measurement circuit 85 via the probe device 70.

In this case, the prescribed unit may be, for example, a predetermined number of processed substrates, or a predetermined processing time. That is, data during the plasma processing for the processing of a plurality of substrates is acquired. Further, the acquired data is a current value (current Iₚ). Further, the acquired data includes fundamental harmonic data and second harmonic data obtained by the FFT analysis of the current value (the current Iₚ). Further, the fundamental harmonic data includes the amplitude of the real part of the fundamental current harmonic and the amplitude of the imaginary part of the fundamental current harmonic, and the second harmonic data includes the amplitude of the real part of the second current harmonic and the amplitude of the imaginary part of the second current harmonic. Alternatively, the fundamental harmonic data may include the amplitude and phase of the fundamental current harmonic, and the second harmonic data may include the amplitude and phase of the second current harmonic.

Next, the controller 33 executes fitting processing between state parameters indicating the state of the plasma and the acquired data, and performs an operation of deriving true plasma state parameters and parameters of the measurement circuit 85.

Here, the state parameters indicating the state of the plasma include the plasma electron temperature Tₑ and the plasma electron density nₑ. The true plasma state parameters are the plasma electron temperature Tₑ and the plasma electron density nₑ derived in consideration of the influence of the deposited film (the insulating film or the conductive film).

Further, the parameters of the measurement circuit 85 include parameters of the deposition film (the insulating film or the conductive film). The parameters of the measurement circuit 85 include the capacitive component C_{SiN} of the insulating film, the resistive component R_{f} of the conductive film, and the capacitive component C_{f} of the conductive film.

The controller 33 includes a mechanism for performing simulation. The simulation may use a harmonic balance method, a Runge-Kutta method, or the like. Thus, the controller 33 executes the fitting processing by the simulation using the acquired data of the probe device 70 and the circuit model illustrated in FIG. 5B to derive the parameters.

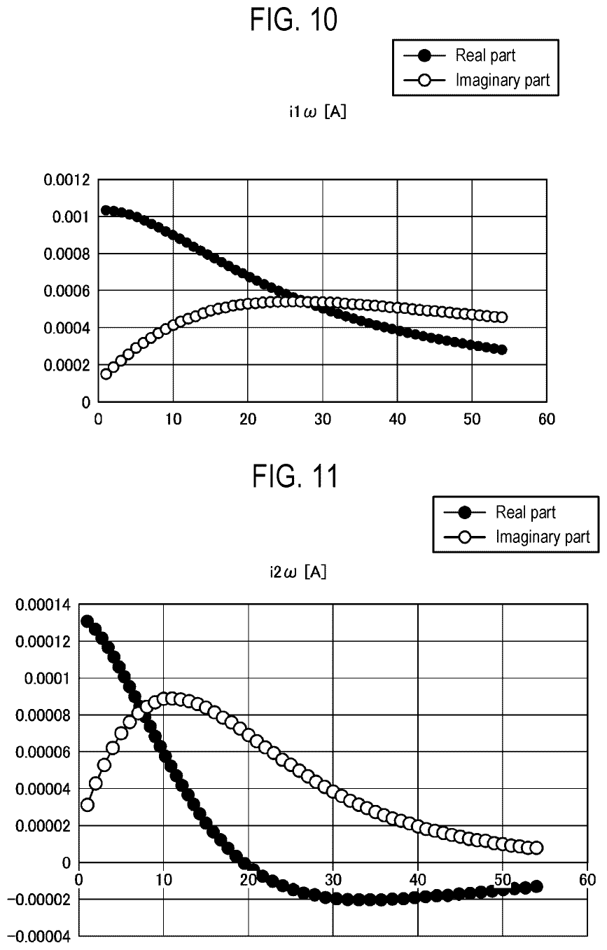

Next, an operation of deriving information (parameters) about the plasma and the deposited film based on the acquired data of the probe device 70 will be described with reference to FIGS. 10 to 15. In addition, in the following description, it is assumed that the acquired data of the probe device 70 includes the amplitude of the real part of the fundamental current harmonic (i1ω), the amplitude of the imaginary part of the fundamental current harmonic (i1ω), the amplitude of the real part of the second current harmonic (i2ω), and the amplitude of the imaginary part of the second current harmonic (i2ω).

FIG. 10 is a graph illustrating an example of extracted amplitudes of the real part and the imaginary part of a fundamental current harmonic. In FIG. 10, the horizontal axis represents the lot number of substrate processing. The vertical axis represents the amplitude of the real part of the fundamental current harmonic (i1ω) and the amplitude of the imaginary part of the fundamental current harmonic (i1ω). FIG. 11 is a graph illustrating an example of extracted amplitudes of the real part and the imaginary part of the second current harmonic. In FIG. 11, the horizontal axis represents the lot number of substrate processing. The vertical axis represents the amplitude of the real part of the second current harmonic (i2ω) and the amplitude of the imaginary part of the second current harmonic (i2ω).

Here, FIG. 10 illustrates results of the current value extracted from the data illustrated in FIG. 8 at a predetermined timing (for example, 30 seconds after plasma ignition) in representative data of each lot. Similarly, FIG. 11 illustrates results of the current value extracted from the data illustrated in FIG. 9 at a predetermined timing (for example, 30 seconds after the plasma ignition) in representative data of each lot.

In this case, the representative data of each lot may be, for example, data at the timing when the plasma becomes stable after the plasma ignition. Alternatively, the representative data of each lot may be an average value in the lot.

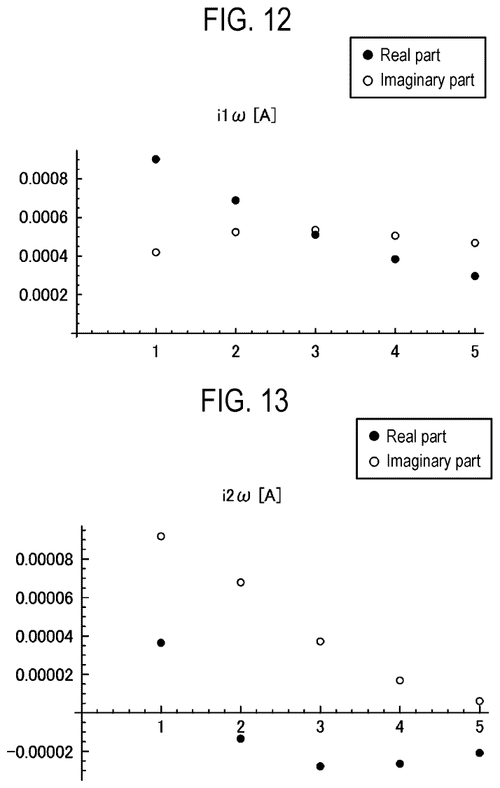

FIG. 12 is a graph illustrating an example of further extracted amplitudes of the real part and the imaginary part of the fundamental current harmonic. In FIG. 12, the horizontal axis represents the number of data. The vertical axis represents the amplitude of the real part of the fundamental current harmonic (i1ω) and the amplitude of the imaginary part of the fundamental current harmonic (i1ω). FIG. 13 is a graph illustrating an example of further extracted amplitudes of the real part and the imaginary part of the second current harmonic. In FIG. 13, the horizontal axis represents the number of data. The vertical axis represents the amplitude of the real part of the second current harmonic (i2ω) and the amplitude of the imaginary part of the second current harmonic (i2ω).

Here, for the purpose of reducing computational resources, the data illustrated in FIG. 10 is decimated to one-tenth the number of data, as illustrated in FIG. 12. Similarly, the data illustrated in FIG. 11 is decimated to one-tenth the number of data, as illustrated in FIG. 13.

Next, the controller 33 performs the simulation of the circuit model illustrated in FIG. 5B based on the acquired data of the probe device 70 illustrated in FIGS. 12 and 13 to estimate fitting parameters. In this case, the fitting parameters to be estimated include the plasma electron temperature Tₑ, the plasma electron density nₑ, the resistive component R_{f} of the conductive film, the capacitive component C_{f} of the conductive film, and the capacitive component reference value c₀ of the insulating film.

In the circuit model illustrated in FIG. 5B, the parasitic capacitance Cₛ may be estimated from a dark current. That is, the parasitic capacitance Cₛ is a known value. Further, the capacitance C of the blocking capacitor 72 and the resistance R for current measurement are also known values. In the following description, it is assumed that:
Parasitic capacitance Cₛ=5.4×10⁻¹⁰ [F];
Capacitance C=10 [μF]; and
Resistance R=10 [Ω].

The film thickness of the insulating film deposited on the surface of the probe device 70 is proportional to the number of processed substrates W after the dry cleaning. When the number of processed substrates W after the dry cleaning is N1, the capacitive component of the insulating film may be expressed as C_{SiN}=c₀/N1 [F]. In addition, the capacitive component reference value c₀ of the insulating film is an example of the fitting parameters to be estimated.

The film thickness of the conductive film deposited on the surface of the probe device 70 is proportional to the number of dry cleanings. When the number of dry cleanings is N2, the capacitive component C_{f} of the conductive film may be expressed as C_{f0}/N2 [F], and the resistive component R_{f} of the conductive film may be expressed as R_{f0}×N2 [Ω]. In addition, the capacitive component C_{f} of the conductive film and the resistive component R_{f} of the conductive film are examples of the fitting parameters to be estimated.

Further, between the dry cleaning and a subsequent dry cleaning, the film thickness of the conductive film is assumed to be constant, and the capacitive component C_{f} and the resistive component R_{f} of the conductive film are assumed to remain constant.

Further, the plasma electron temperature Tₑ and the plasma electron density nₑ are assumed to remain constant in each data on the premise that it has been confirmed there is no change in the state of the plasma processing apparatus. In addition, the plasma electron temperature Tₑ and the plasma electron density nₑ are examples of the fitting parameters to be estimated.

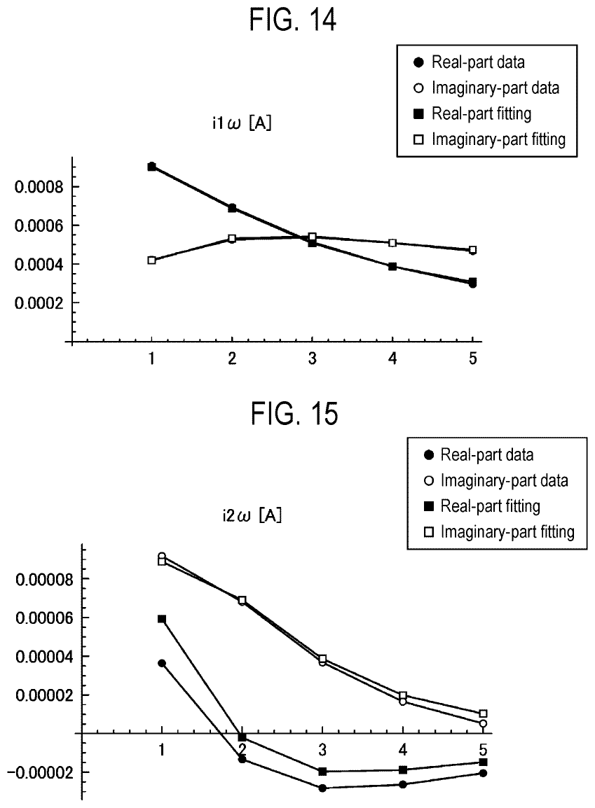

FIG. 14 is a graph illustrating an example of fitted amplitudes of the real part and the imaginary part of the fundamental current harmonic. In FIG. 14, the horizontal axis represents the number of data. The vertical axis represents amplitude data and fitted data of the real part and the imaginary part of the fundamental current harmonic (i1ω). FIG. 15 is a graph illustrating an example of fitted amplitudes of the real part and the imaginary part of the second current harmonic. In FIG. 15, the horizontal axis represents the number of data. The vertical axis represents amplitude data and fitted data of the real part and the imaginary part of the second current harmonic (i2ω).

The controller 33 performs fitting of the fitting parameters by simulation. In the following description, it is assumed that the fitting parameters are calculated as follows:
C_{f0}=4.2×10⁻⁸ [F];
R_{f0}=2.9×10¹⁰ [Ω·m];
C_{SiN}=2.9×10⁻⁸ [F];
Tₑ=2.64 [eV]; and
nₑ=3.17×10¹⁰ [cm⁻³].

In FIG. 14, measured data of the real part of the fundamental current harmonic (i1ω) is indicated by black circles, and measured data of the imaginary part of the fundamental current harmonic (i1ω) is indicated by white circles. Further, fitted data of the real part of the fundamental current harmonic (i1ω) is indicated by black squares, and fitted data of the imaginary part of the fundamental current harmonic (i1ω) is indicated by white squares (However, in FIG. 14, the circles and squares almost overlap).

In FIG. 15, measured data of the real part of the second current harmonic (i2ω) is indicated by black circles, and measured data of the imaginary part of the second current harmonic (i2ω) is indicated by white circles. Further, fitted data of the real part of the second current harmonic (i2ω) is indicated by black squares, and fitted data of the imaginary part of the second current harmonic (i2ω) is indicated by white squares.

As illustrated in FIGS. 14 and 15, the fitted data approximately coincides with the measured data. In other words, by fitting the data through the simulation, the state of the plasma (the plasma electron temperature Tₑ and the plasma electron density nₑ) and the state of the deposited film (the capacitive component C_{SiN} of the insulating film, the capacitive component C_{f} of the conductive film, and the resistive component R_{f} of the conductive film) may be estimated with high accuracy.

In addition, the controller 33 has been described as estimating the state of the plasma (the plasma electron temperature Tₑ and the plasma electron density nₑ) and the state of the deposition film (the capacitive component C_{SiN} of the insulating film, the capacitive component C_{f} of the conductive film, and resistive component R_{f} of the conductive film) by the simulation based on the acquired data of the probe device 70, but is not limited thereto. The controller 33 may previously store a table that associates the acquired data of the probe device 70 with the state of the plasma (the plasma electron temperature Tₑ and the plasma electron density nₑ) and the state of the deposited film (the capacitive component C_{SiN} of the insulating film, the capacitive component C_{f} of the conductive film, and the resistive component R_{f} of the conductive film). In this case, the controller 33 may estimate the state of the plasma (the plasma electron temperature Tₑ and the plasma electron density nₑ) and the state of the deposited film (the capacitive component C_{SiN} of the insulating film, the capacitive component C_{f} of the conductive film, and the resistive component R_{f} of the conductive film) based on the acquired data of the probe device 70 and the table.

Further, the controller 33 may use derived information (information about the plasma and information about the deposited film) to determine the timing of the dry cleaning processing (S102) or the timing of the wet cleaning processing. Further, the controller 33 may issue an alert when the timing is determined to have been reached. Further, the controller 33 may perform feedback control of plasma generation (for example, power control of the microwave outputter 30) based on restored information (the information about the plasma and the information about the deposited film). Further, the controller 33 may determine whether or not the plasma processing apparatus 100 is normal or abnormal based on the restored information (the information about the plasma and the information about the deposited film). Further, the controller 33 may issue an alert when the plasma processing apparatus 100 is determined to be abnormal.

According to one aspect, it is possible to provide a plasma measurement method and a plasma measurement system for measuring a state of plasma while minimizing the influence of a conductive film.

Although the plasma processing apparatus 100 has been described above, the present disclosure is not limited to the above-described embodiments, and various modifications and improvements are possible within the scope of the gist of the present disclosure as set forth in the claims.

What is claimed is:

1. A plasma measurement method of measuring a state of plasma using a plasma measurement system,
wherein the plasma measurement system comprises:
a probe device provided in a plasma processing apparatus; and
a measurement circuit including a signal generator configured to output an alternating-current voltage,
the plasma measurement method comprising:
acquiring, by the measurement circuit via the probe device, data including at least fundamental harmonic data and second harmonic data during plasma processing of a prescribed unit; and
deriving a plasma state parameter and a parameter of the measurement circuit based on the acquired data.

2. The plasma measurement method of claim 1, wherein the plasma processing includes:
a process in which, when film formation processing is performed on a substrate in the plasma processing apparatus, an insulating film is deposited on the probe device and a capacitive component is added to the measurement circuit; and
a process in which, when dry cleaning processing is performed in the plasma processing apparatus, a conductive film is deposited on the probe device and a capacitive component and a resistive component are added to the measurement circuit.

3. The plasma measurement method of claim 1, further comprising, after the deriving the plasma state parameter and/or the parameter of the measurement circuit, determining whether or not each of the derived parameters is normal or abnormal.

4. The plasma measurement method of claim 2, wherein the plasma state parameter includes a plasma electron temperature and a plasma electron density, and the parameter of the measurement circuit includes a capacitive component added to the measurement circuit by the film formation processing, a capacitive component added to the measurement circuit by the dry cleaning processing, and a resistive component added to the measurement circuit by the dry cleaning processing.

5. The plasma measurement method of claim 1, wherein the deriving the plasma state parameter and the parameter of the measurement circuit based on the acquired data uses a harmonic balance method or a Runge-Kutta method.

6. A plasma measurement system for measuring a state of plasma, comprising:
a probe device provided in a plasma processing apparatus;
a measurement circuit including a signal generator configured to output an alternating-current voltage; and
a controller,
wherein the controller is configured to be capable of executing:
acquiring, by the measurement circuit via the probe device, data including at least fundamental harmonic data and second harmonic data during plasma processing of a prescribed unit; and
deriving a plasma state parameter and a parameter of the measurement circuit based on the acquired data.
